(19) United States
(12) Patent Application Publication
(10) Pub. No.: US 2018/0037981 A1
(43) Pub. Date: Feb. 8, 2018

(54) TEMPERATURE-CONTROLLED CHALCOGEN VAPOR DISTRIBUTION APPARATUS AND METHOD FOR UNIFORM CIGS DEPOSITION

(71) Applicant: BEIJING APOLLO DING RONG SOLAR TECHNOLOGY CO., LTD., Beijing (CN)

(72) Inventors: Robert D. Tas, Aromas, CA (US); Heinrich Von Bunau, Santa Clara, CA (US); Robert Martinson, Palo Alto, CA (US)

(21) Appl. No.: 15/227,688

(22) Filed: Aug. 3, 2016

(51) Int. Cl. C23C 14/00; H01J 37/32; C23C 14/06; H01L 31/18; H01L 31/032

(52) U.S. Cl. CPC C23C 14/0057; H01L 31/18; H01L 31/0324; C23C 14/0623; C23C 14/0063; H01J 37/32449; H01J 37/32715

(57) ABSTRACT

A deposition system and method for depositing a uniform film of a chalcogen-containing compound semiconductor are provided. The deposition system includes a vacuum enclosure connected to a vacuum pump, a sputtering system comprising at least one sputtering target located in the vacuum enclosure, a chalcogen-containing gas source, and a gas distribution manifold having a supply side and a distribution side. The distribution side has a plurality of opening regions having independent temperature control and the supply side is connected to the chalcogen-containing gas source. A method of reactive sputter depositing a chalcogen-containing compound semiconductor material includes sputtering at least one metal component of the chalcogen-containing compound semiconductor material onto the substrate, and providing a higher chalcogen flux to ends of the substrate than to a middle of the substrate to form the chalcogen-containing compound semiconductor material.

### BACKGROUND

The present disclosure is directed generally to an apparatus and method for depositing a metal chalcogenide material, and particularly to an apparatus and method for depositing a copper indium gallium selenide material using a selenium manifold with separate heaters.

A “thin-film” photovoltaic material refers to a polycrystalline or amorphous photovoltaic material that is deposited as a layer on a substrate that provides structural support. The thin-film photovoltaic materials are distinguished from single crystalline semiconductor materials that have a higher manufacturing cost. Some of the thin-film photovoltaic materials that provide high conversion efficiency include chalcogen-containing compound semiconductor material, such as copper indium gallium selenide (“CIGS”).

Thin-film photovoltaic cells (also known as photovoltaic cells) may be manufactured using a roll-to-roll coating system based on sputtering, evaporation, or chemical vapor deposition (CVD) techniques. A thin foil substrate, such as a foil web substrate, is fed from a roll in a linear belt-like fashion through the series of individual vacuum chambers or a single divided vacuum chamber where it receives the required layers to form the thin-film photovoltaic cells. In such a system, a foil having a finite length may be supplied on a roll. The end of a new roll may be coupled to the end of a previous roll to provide a continuously fed foil layer.

### SUMMARY

According to an aspect of the present disclosure, a deposition system for deposition of a chalcogen-containing compound semiconductor material is provided. The deposition system includes a vacuum enclosure connected to a vacuum pump, a sputtering system comprising at least one sputtering target located in the vacuum enclosure, a chalcogen-containing gas source, and a gas distribution manifold having a supply side and a distribution side. The distribution side has a plurality of opening regions having independent temperature control and the supply side is connected to the chalcogen-containing gas source.

According to another aspect of the present disclosure, a deposition system for deposition of a copper indium gallium selenide compound semiconductor material includes a vacuum enclosure connected to a vacuum pump, a sputtering system comprising at least one copper, gallium and/or indium sputtering target located in the vacuum enclosure, a selenium evaporator, a gas distribution manifold having a supply side and a distribution side, wherein the distribution side has a plurality of opening regions and the supply side is connected to the selenium evaporator, and means for independently heating at least a first opening region of the plurality of opening regions to a different temperature than at least a second opening region of the plurality of opening regions. The means for independently heating may comprise independently controlled heaters.

According to another aspect of the present disclosure, a method of reactive sputter depositing a chalcogen-containing compound semiconductor material includes sputtering at least one metal component of the chalcogen-containing compound semiconductor material onto the substrate, and providing a higher chalcogen flux to ends of the substrate than to a middle of the substrate to form the chalcogen-containing compound semiconductor material.

### BRIEF DESCRIPTION OF THE DRAWINGS

FIG. 1 is a schematic vertical cross sectional view of a thin-film photovoltaic cell according to an embodiment of the present disclosure.

FIG. 2 is a schematic top view diagram of a first exemplary modular deposition apparatus that can be used to manufacture the photovoltaic cell illustrated in FIG. 1 according to an embodiment of the present disclosure.

FIG. 3 is a schematic top view diagram of a second exemplary modular deposition apparatus that can be used to manufacture the photovoltaic cell illustrated in FIG. 1 according to an embodiment of the present disclosure.

FIG. 4 is a schematic top view diagram of an exemplary sealing connection unit according to an embodiment of the present disclosure.

FIG. 5 is a schematic top view diagram of an exemplary module including a deposition system for a chalcogen-containing compound semiconductor material according to an embodiment of the present disclosure.

FIGS. 6A and 6B are top view schematic diagrams of exemplary gas distribution manifolds according to an embodiment of the present disclosure.

FIGS. 7A-7C are front views of exemplary sets of opening regions of a gas distribution manifold according to an embodiment of the present disclosure. FIG. 7D is a three dimensional perspective view of the gas distribution manifold of FIG. 7A located in the module of FIG. 5.

FIG. 8 is a side cross sectional view of an exemplary temperature control system for a heating element according to an embodiment of the present disclosure.

### DETAILED DESCRIPTION

As discussed above, the present disclosure is directed to an apparatus and method for depositing a copper indium gallium selenide material. The web substrate typically has a width (i.e., a height of the web substrate for a vertically positioned web substrate, which is perpendicular to the length (i.e., movement direction) of the web substrate) of at least 10 cm, and oftentimes a width of about 1 meters or more, such as 1 to 5 meters. Deposition of a film with a uniform thickness and/or composition as a function of a large web substrate width is a challenge even in a large deposition chamber. Particularly, metal chalcogen containing compound semiconductor materials such as copper indium gallium chalcogenide (e.g., CIGS) have a deposition rate that is highly sensitive to the deposition temperature. Further, the composition of such metal chalcogen containing compound semiconductor materials can vary significantly depending on rate of incorporation of a chalcogen-containing gas (e.g., evaporated selenium) during the deposition process. In one embodiment, without wishing to be bound by a particular theory, the present inventors determined that a higher chalcogen (e.g., selenium) flux is desirable at the ends (i.e., top and bottom portions of a vertically positioned web substrate) than in the middle of the vertically positioned substrate to obtain a metal chalcogen containing compound semiconductor material (e.g., CIGS) with a more uniform thickness and/or composition as a function of substrate width (i.e., height). In one embodiment, a chalcogen manifold contains independently controllable heating elements which can be independently controlled to provide the higher chalcogen (e.g., selenium vapor) flux to the ends than the middle of the web substrate.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. As used herein, a first element located “on” a second element can be located on the exterior side of a surface of the second element or on the interior side of the second element. As used herein, a first element is located “directly on” a second element if there exist a direct physical contact between a surface of the first element and a surface of the second element.

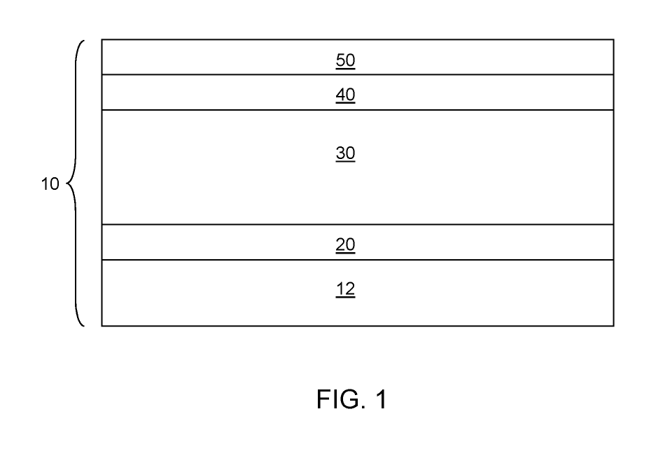

Referring to FIG. 1, a vertical cross-sectional view of a photovoltaic cell 10 is illustrated. The photovoltaic cell 10 includes a substrate, such as an electrically conductive substrate 12, a first electrode 20, a p-doped semiconductor layer 30, an n-doped semiconductor layer 40, a second electrode 50, and an optional antireflective (AR) coating layer (not shown).

The substrate 12 is preferably a flexible, electrically conductive material, such as a metallic foil that is fed into a system of one or more process modules as a web for deposition of additional layers thereupon. For example, the metallic foil of the conductive substrate 12 can be a sheet of a metal or a metallic alloy such as stainless steel, aluminum, or titanium. If the substrate 12 is electrically conductive, then it may comprise a part of the back side (i.e., first) electrode of the cell 10. Thus, the first (back side) electrode of the cell 10 may be designated as (20, 12). Alternatively, the conductive substrate 12 may be an electrically conductive or insulating polymer foil. Still alternatively, the substrate 12 may be a stack of a polymer foil and a metallic foil. In another embodiment, the substrate 12 may be a rigid glass substrate or a flexible glass substrate. The thickness of the substrate 12 can be in a range from 100 microns to 2 mm, although lesser and greater thicknesses can also be employed.

The first or back side electrode 20 may comprise any suitable electrically conductive layer or stack of layers. For example, electrode 20 may include a metal layer, which may be, for example, molybdenum. Alternatively, a stack of molybdenum and sodium and/or oxygen doped molybdenum layers may be used instead, as described in U.S. Pat. No. 8,134,069, which is incorporated herein by reference in its entirety. In another embodiment, the first electrode 20 can include a molybdenum material layer doped with K and/or Na, i.e., MoKₓ or Mo(Na,K)ₓ, in which x can be in a range from 1.0×10⁻⁶ to 1.0×10⁻². The electrode 20 can have a thickness in a range from 500 nm to 1 micron, although lesser and greater thicknesses can also be employed.

The p-doped semiconductor layer 30 can include a p-type sodium doped copper indium gallium selenide (CIGS), which functions as a semiconductor absorber layer. The thickness of the p-doped semiconductor layer 30 can be in a range from 1 microns to 5 microns, although lesser and greater thicknesses can also be employed.

The n-doped semiconductor layer 40 includes an n-doped semiconductor material such as CdS, ZnS, ZnSe, or an alternative metal sulfide or a metal selenide. The thickness of the n-doped semiconductor layer 40 is typically less than the thickness of the p-doped semiconductor layer 30, and can be in a range from 30 nm to 100 nm, although lesser and greater thicknesses can also be employed. The junction between the p-doped semiconductor layer 30 and the n-doped semiconductor layer 40 is a p-n junction. The n-doped semiconductor layer 40 can be a material which is substantially transparent to at least part of the solar radiation. The n-doped semiconductor layer 40 is also referred to as a window layer or a buffer layer.

The second (e.g., front side or top) electrode 50 comprises one or more transparent conductive layers 50. The transparent conductive layer 50 is conductive and substantially transparent. The transparent conductive layer 50 can include one or more transparent conductive materials, such as ZnO, indium tin oxide (ITO), Al doped ZnO (“AZO”), Boron doped ZnO (“BZO”), or a combination or stack of higher resistivity AZO and lower resistivity ZnO, ITO, AZO and/or BZO layers. The second electrode 50 contacts an electrically conductive part (e.g., a metal wire or trace) of an interconnect, such as an interconnect described in U.S. Pat. No. 8,912,429, issued Dec. 16, 2014, which is incorporated herein by reference in its entirety, or any other suitable interconnect that is used in photovoltaic panels.

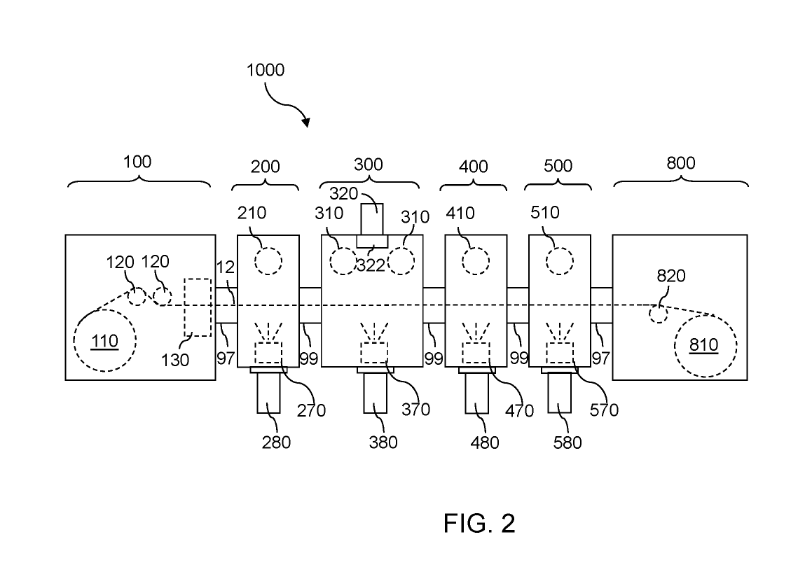

Referring now to FIG. 2, an apparatus 1000 for forming the photovoltaic cell 10 illustrated in FIG. 1 is shown. The apparatus 1000 is a first exemplary modular deposition apparatus that can be used to manufacture the photovoltaic cell illustrated in FIG. 1. The apparatus 1000 includes an input unit 100, a first process module 200, a second process module 300, a third process module 400, a fourth process module 500, and an output unit 800 that are sequentially connected to accommodate a continuous flow of the substrate 12 in the form of a web foil substrate layer through the apparatus. The modules (100, 200, 300, 400, 500) may comprise the modules described in U.S. Pat. No. 9,303,316, issued on Apr. 5, 2016, incorporated herein by reference in its entirety, or any other suitable modules. The first, second, third, and fourth process modules (200, 300, 400, 500) can be under vacuum by first, second, third, and fourth vacuum pumps (280, 380, 480, 580), respectively. The first, second, third, and fourth vacuum pumps (280, 380, 480, 580) can provide a suitable level of respective base pressure for each of the first, second, third, and fourth process modules (200, 300, 400, 500), which may be in a range from 1.0×10⁻⁹ Torr to 1.0×10⁻² Torr, and preferably in range from 1.0×10⁻⁹ Torr to 1.0×10⁻⁵ Torr.

Each neighboring pair of process modules (200, 300, 400, 500) is interconnected employing a vacuum connection unit 99, which can include a vacuum tube and an optional slit valve that enables isolation while the substrate 12 is not present. The input unit 100 can be connected to the first process module 200 employing a sealing connection unit 97. The last process module, such as the fourth process module 500, can be connected to the output unit 800 employing another sealing connection unit 97.

The substrate 12 can be a metallic or polymer web foil that is fed into a system of process modules (200, 300, 400, 500) as a web for deposition of material layers thereupon to form the photovoltaic cell 10. The substrate 12 can be fed from an entry side (i.e., at the input module 100), continuously move through the apparatus 1000 without stopping, and exit the apparatus 1000 at an exit side (i.e., at the output module 800). The substrate 12, in the form of a web, can be provided on an input spool 110 provided in the input module 100.

The substrate 12, as embodied as a metal or polymer web foil, is moved throughout the apparatus 1000 by input-side rollers 120, output-side rollers 820, and additional rollers (not shown) in the process modules (200, 300, 400, 500), vacuum connection units 99, or sealing connection units 97, or other devices. Additional guide rollers may be used. Some rollers (120, 820) may be bowed to spread the web (i.e., the substrate 12), some may move to provide web steering, some may provide web tension feedback to servo controllers, and others may be mere idlers to run the web in desired positions.

The input module 100 can be configured to allow continuous feeding of the substrate 12 by adjoining multiple foils by welding, stapling, or other suitable means. Rolls of substrates 12 can be provided on multiple input spools 110. A joinder device 130 can be provided to adjoin an end of each roll of the substrate 12 to a beginning of the next roll of the substrate 12. In one embodiment, the joinder device 130 can be a welder or a stapler. An accumulator device (not shown) may be employed to provide continuous feeding of the substrate 12 into the apparatus 1000 while the joinder device 130 adjoins two rolls of the substrate 12.

In one embodiment, the input module 100 may perform pre-processing steps. For example, a pre-clean process may be performed on the substrate 12 in the input module 100. In one embodiment, the substrate 12 may pass by a heater array (not shown) that is configured to provide at least enough heat to remove water adsorbed on the surface of the substrate 12. In one embodiment, the substrate 12 can pass over a roller configured as a cylindrical rotary magnetron. In this case, the front surface of substrate 12 can be continuously cleaned by DC, AC, or RF sputtering as the substrate 12 passes around the roller/magnetron. The sputtered material from the substrate 12 can be captured on a disposable shield. Optionally, another roller/magnetron may be employed to clean the back surface of the substrate 12. In one embodiment, the sputter cleaning of the front and/or back surface of the substrate 12 can be performed with linear ion guns instead of magnetrons. Alternatively or additionally, a cleaning process can be performed prior to loading the roll of the substrate 12 into the input module 100. In one embodiment, a corona glow discharge treatment may be performed in the input module 100 without introducing an electrical bias.

The output module 800 can include an output spool 810, which winds the web embodying the photovoltaic cell 10. The photovoltaic cell 10 is the combination of the substrate 12 and the deposited layers (20, 30, 40, 50) thereupon.

In one embodiment, the substrate 12 may be oriented in one direction in the input module 100 and/or in the output module 800, and in a different direction in the process modules (200, 300, 400, 500). For example, the substrate 12 can be oriented generally horizontally in the input module 100 and the output module 800, and generally vertically in the process module(s) (200, 300, 400, 500). A turning roller or turn bar (not shown) may be provided to change the orientation of the substrate 12, such as between the input module 100 and the first process module 200. In an illustrative example, the turning roller or the turn bar in the input module can be configured to turn the web substrate 12 from an initial horizontal orientation to a vertical orientation. Another turning roller or turn bar (not shown) may be provided to change the orientation of the substrate 12, such as between the last process module (such as the fourth process module 500) and the output module 800. In an illustrative example, the turning roller or the turn bar in the input module can be configured to turn the web substrate 12 from the vertical orientation employed during processing in the process modules (200, 300, 400, 500) to a horizontal orientation.

The input spool 110 and optional output spool 810 may be actively driven and controlled by feedback signals to keep the substrate 12 in constant tension throughout the apparatus 1000. In one embodiment, the input module 100 and the output module 800 can be maintained in the air ambient at all times while the process modules (200, 300, 400, 500) are maintained at vacuum during layer deposition.

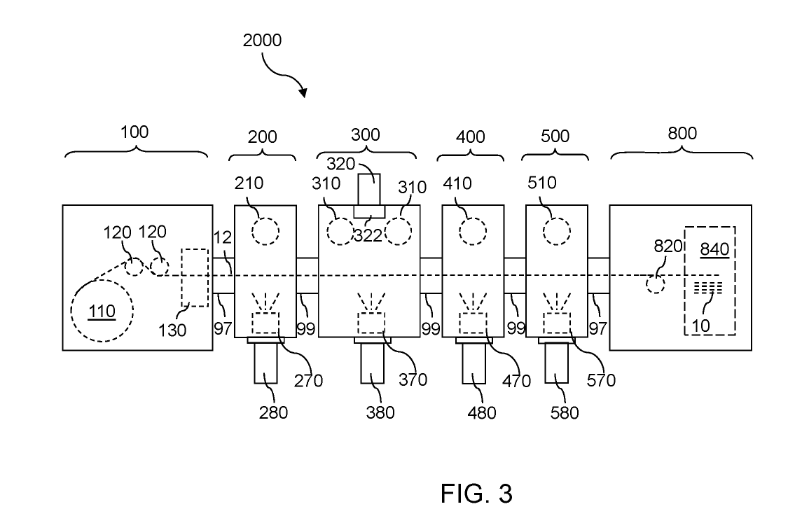

Referring to FIG. 3, a second exemplary modular deposition apparatus 2000 is illustrated, which can be used to manufacture the photovoltaic cell illustrated in FIG. 1. The second exemplary modular deposition apparatus 2000 includes an alternative output module 800, which includes a cutting apparatus 840 instead of an output spool 810. The web containing the photovoltaic cells 10 can be fed into the cutting apparatus 840 in the output module 800, and can be cut into discrete sheets of photovoltaic cells 10 instead of being rolled onto an output spool 810. The discrete sheets of photovoltaic cells are then interconnected using interconnects to form a photovoltaic panel (i.e., a solar module) which contains an electrical output.

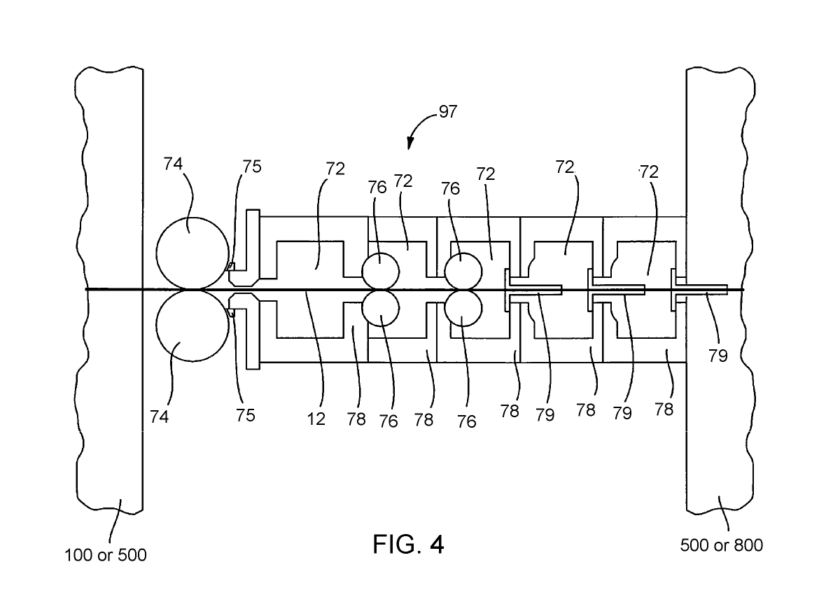

Referring to FIG. 4, an exemplary sealing connection unit 97 is illustrated. The unit 97 may comprise the sealing unit described in U.S. Pat. No. 9,303,316, issued on Apr. 5, 2016, incorporated herein by reference in its entirety, or any other suitable sealing unit. The sealing connection unit 97 is configured to allow the substrate 12 to pass out of a preceding unit (such as the input unit 100 or the last processing chamber such as the fourth process module 500) and into a subsequent unit (such as the first process module 200 or the output unit 800), while impeding the passage of gasses such as atmospheric gasses or processing gasses into or out of the units that the sealing connection unit 97 is adjoined to. The sealing connection unit 97 can include multiple isolation chambers 72. The staged isolation chambers 72 can be configured to maintain internal pressures that graduate from atmospheric on a first side of the sealing connection unit 97 (such as the side of the input module 100 or the output module 800) to a high vacuum on the second side of the sealing connection unit 97 opposite of the first side (such as the side of the first process module 200 or the last process module 500). Multiple isolation chambers 72 can be employed to ensure that the pressure difference at any sealing surface is generally less than the pressure difference between atmospheric pressure and the high vacuum inside the process module.

The substrate 12 enters the sealing unit 97 between two external nip rollers 74. Each of the isolation chambers 72 of the sealing connection unit 97 can be separated by an internal divider 78, which is an internal wall among the isolation chambers 72. A pair of internal nip rollers 76, similar in function and arrangement to that of the external rollers 74, may be provided proximate to the internal dividers 78 between some of the neighboring internal chambers 72. The passage between the internal rollers 76 is generally closed off by rolling seals between the internal rollers 76 and the substrate 12. The internal dividers 78 may include curved sockets or contours that are configured to receive internal rollers 76 of a similar radius of curvature. The passage of gasses from one isolation chamber 72 to a neighboring, lower pressure internal chamber 72 may be reduced by a simple surface to surface contact between the internal roller 76 and the divider 78. In other embodiments, a seal such as a wiper seal may be provided for some or all of the internal rollers 76 to further reduce the infiltration of gasses into neighboring isolation chambers 72. The internal rollers 76 may be freely spinning rollers, or may be powered to control the rate of passage of the substrate 12 through the sealing connection unit 97. Between other chambers 72, the passage of gasses between neighboring chambers 72 may be limited by parallel plate conductance limiters 79. The parallel plate conductance limiters 79 are generally flat, parallel plates that are arranged parallel to the surface of the substrate 12 and are spaced apart a distance slightly larger than the thickness of the substrate 12. The parallel plate conductance limiters 79 allow the substrate to pass between the chambers 72 while limiting the passage of gasses between chambers 72.

In one embodiment, the sealing connection unit 97 may also include inert gas purge at the in-feed nip. In one embodiment, the sealing connection unit 97 may also include optional reverse crown or spreading rollers. The difference in pressure between neighboring chambers may deform the internal rollers 76, causing them to deflect or crown towards the chamber with a lower pressure. The reverse crown rollers are placed such that they correct for vacuum-induced deflection of the internal rollers 76. Thus, other than the slight deformation corrected by the reverse crown rollers, the sealing connection unit 97 is configured to pass the web substrate without bending or turning or scratching the web substrate 12.

Referring back to FIGS. 2 and 3, each of the first, second, third, and fourth process modules (200, 300, 400, 500) can deposit a respective material layer to form the photovoltaic cell 10 (shown in FIG. 1) as the substrate 12 passes through the first, second, third, and fourth process modules (200, 300, 400, 500) sequentially.

Optionally, one or more additional process modules (not shown) may be added between the input module 100 and the first process module 200 to sputter a back side protective layer on the back side of the substrate 12 before deposition of the first electrode 20 in the first process module 200. Further, one or more barrier layers may be sputtered over the front surface of the substrate 12 prior to deposition of the first electrode 20. Alternatively or additionally, one or more process modules (not shown) may be added between the first process module 200 and the second process module 300 to sputter one or more adhesion layers between the first electrode 20 and the p-doped semiconductor layer 30 including a chalcogen-containing compound semiconductor material.

The first process module 200 includes a first sputtering target 210, which includes the material of the first electrode 20 in the photovoltaic cell 10 illustrated in FIG. 1. A first heater 270 can be provided to heat the web substrate 12 to an optimal temperature for deposition of the first electrode 20. In one embodiment, a plurality of first sputtering targets 210 and a plurality of first heaters 270 may be employed in the first process module 200. In one embodiment, the at least one first sputtering target 210 can be mounted on dual cylindrical rotary magnetron(s), or planar magnetron(s) sputtering targets, or RF sputtering targets. In one embodiment, the at least one first sputtering target 210 can include a molybdenum target, a molybdenum-sodium, and/or a molybdenum-sodium-oxygen target, as described in U.S. Pat. No. 8,134,069, incorporated herein by reference in its entirety.

The portion of the substrate 12 on which the first electrode 20 is deposited is moved into the second process module 300. A p-doped chalcogen-containing compound semiconductor material is deposited to form the p-doped semiconductor layer 30, such as a sodium doped CIGS absorber layer. In one embodiment, the p-doped chalcogen-containing compound semiconductor material can be deposited employing reactive alternating current (AC) magnetron sputtering in a sputtering atmosphere that includes argon and a chalcogen-containing gas at a reduce pressure. In one embodiment, multiple metallic component targets 310 including the metallic components of the p-doped chalcogen-containing compound semiconductor material can be provided in the second process module 300.

As used herein, the “metallic components” of a chalcogen-containing compound semiconductor material refers to the non-chalcogenide components of the chalcogen-containing compound semiconductor material. For example, in a copper indium gallium selenide (CIGS) material, the metallic components include copper, indium, and gallium. The metallic component targets 310 can include an alloy of all non-metallic materials in the chalcogen-containing compound semiconductor material to be deposited. For example, if the chalcogen-containing compound semiconductor material is a CIGS material, the metallic component targets 310 can include an alloy of copper, indium, and gallium. More than two targets 310 may be used.

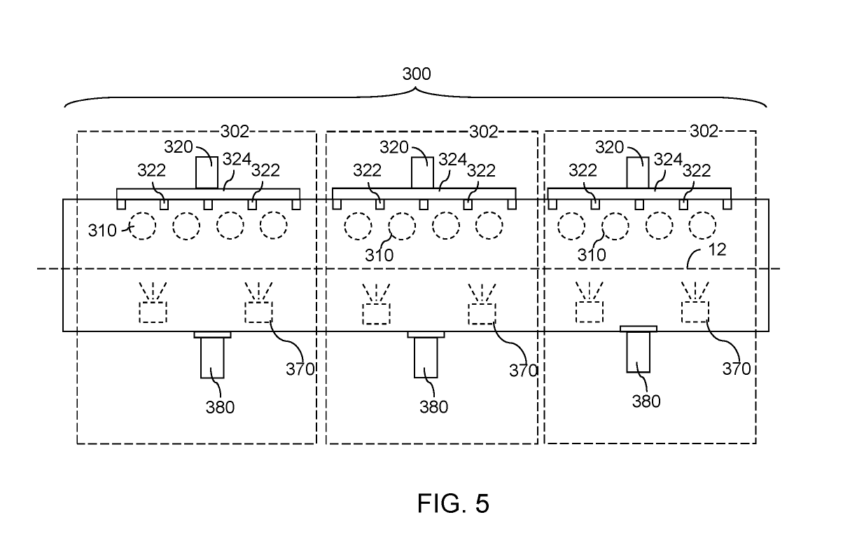

At least one chalcogen-containing gas source 320 (such as a selenium evaporator) and at least one gas distribution manifold 322 can be provided on the second process module 300 to provide a chalcogen-containing gas into the second process module 300. The chalcogen-containing gas provides chalcogen atoms that are incorporated into the deposited chalcogen-containing compound semiconductor material. While FIGS. 2 and 3 schematically illustrate a second process module 300 including two metallic component targets 310, a single chalcogen-containing gas source 320, and a single gas distribution manifold 322, multiple instances of the chalcogen-containing gas source 320 and/or the gas distribution manifold 322 can be provided in the second process module 300 as illustrated in FIG. 5.

FIG. 5 illustrates an exemplary configuration for the second process module 300. In this configuration, the second process module 300 is provided with three sets of chalcogen-containing compound semiconductor material deposition units 302. Each chalcogen-containing compound semiconductor material deposition unit 302 may be a separate deposition chamber or different portions of the same deposition chamber. Each deposition unit includes a separate chalcogen-containing gas source 320 (e.g., selenium evaporator) and one or more separate targets 310. For example, in one embodiment illustrated in FIG. 5, each distribution unit 302 includes a dedicated second vacuum pump 380, one or more (e.g., pair) of dedicated second heaters 370, one or more (e.g. four) dedicated metallic component targets 310 (e.g., CIG targets), a dedicated chalcogen-containing gas source 320, one or more (e.g., five) gas distribution manifolds 322, and a dedicated connection manifold 324 that connects the chalcogen-containing gas source 320 to the gas distribution manifolds 322. As many chalcogen-containing compound semiconductor material deposition units 302 can be provided along the path of the substrate 12 as is needed to achieve the target thickness and composition (e.g., Cu, In and/or Ga composition gradient) for the p-doped chalcogen-containing compound semiconductor material (e.g., for the CIGS absorber 30 shown in FIG. 1). The number of second vacuum pumps 380 may, or may not, coincide with the number of the deposition units 302. The number of second heaters 370 may, or may not, be commensurate with the number of the deposition units 302. Likewise, the number of manifolds 322 and targets 310 may be different in different deposition units 302. Likewise, the composition of each target 310 may be different in different deposition unit 302 (e.g., the Cu:(Ga+In) or Ga:In ratio in the targets 310 in different deposition units 302 may vary to obtain a CIGS absorber with a graded composition).

The chalcogen-containing gas source 320 includes a source material for the chalcogen-containing gas. The species of the chalcogen-containing gas can be selected to enable deposition of the target chalcogen-containing compound semiconductor material to be deposited. For example, if a CIGS material is to be deposited for the p-doped semiconductor layer 30, the chalcogen-containing gas may be selected, for example, from hydrogen selenide (H₂Se) and selenium vapor. In case the chalcogen-containing gas is hydrogen selenide, the chalcogen-containing gas source 320 can be a cylinder of hydrogen selenide. In case the chalcogen-containing gas is selenium vapor, the chalcogen-containing gas source 320 can be a selenium evaporator, such as an effusion cell that can be heated to generate selenium vapor. Each second heater 370 can be a radiation heater that maintains the temperature of the web substrate 12 at the deposition temperature, which can be in a range from 400° C. to 800° C., such as a range from 500° C. to 700° C., which is preferable for CIGS deposition.

The chalcogen incorporation during deposition of the chalcogen-containing compound semiconductor material determines the properties and quality of the chalcogen-containing compound semiconductor material in the p-doped semiconductor layer 30. When the chalcogen-containing gas is supplied in the gas phase at an elevated temperature, the chalcogen atoms from the chalcogen-containing gas can be incorporated into the deposited film by absorption and subsequent bulk diffusion. This process is referred to as chalcogenization, in which complex interactions occur to form the chalcogen-containing compound semiconductor material. The p-type doping in the p-doped semiconductor layer 30 is induced by controlling the degree of deficiency of the amount of chalcogen atoms with respect the amount of non-chalcogen atoms (such as copper atoms, indium atoms, and gallium atoms in the case of a CIGS material) deposited from the metallic component targets 310.

In one embodiment, each metallic component target 310 can be employed with a respective magnetron (not expressly shown) to deposit a chalcogen-containing compound semiconductor material with a respective composition. In one embodiment, the composition of the metallic component targets 310 can be gradually changed along the path of the substrate 12 so that a graded chalcogen-containing compound semiconductor material can be deposited in the second process module 300. For example, if a CIGS material is deposited as the chalcogen-containing compound semiconductor material of the p-doped semiconductor layer 30, the atomic percentage of gallium of the deposited CIGS material can increase as the substrate 12 progresses through the second process module 300. In this case, the p-doped CIGS material in the p-doped semiconductor layer 30 of the photovoltaic cell 10 can be graded such that the band gap of the p-doped CIGS material increases with distance from the interface between the first electrode 20 and the p-doped semiconductor layer 30.

In one embodiment, the total number of metallic component targets 310 may be in a range from 3 to 20. In an illustrative example, the composition of the deposited chalcogen-containing compound semiconductor material (e.g., the p-doped CIGS material absorber 30) can be graded such that the band gap of the p-doped CIGS material varies (e.g., increases or decreases gradually or in steps) with distance from the interface between the first electrode 20 and the p-doped semiconductor layer 30. For example, the band gap can be about 1 eV at the interface with the first electrode 20, and can be about 1.3 eV at the interface with subsequently formed n-doped semiconductor layer 40.

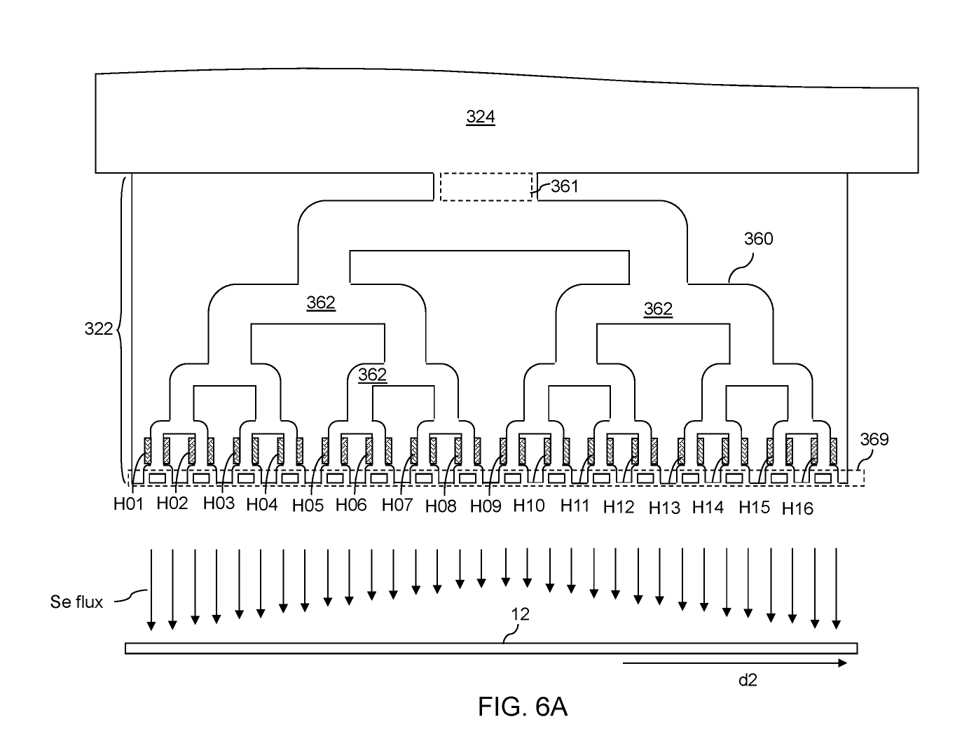

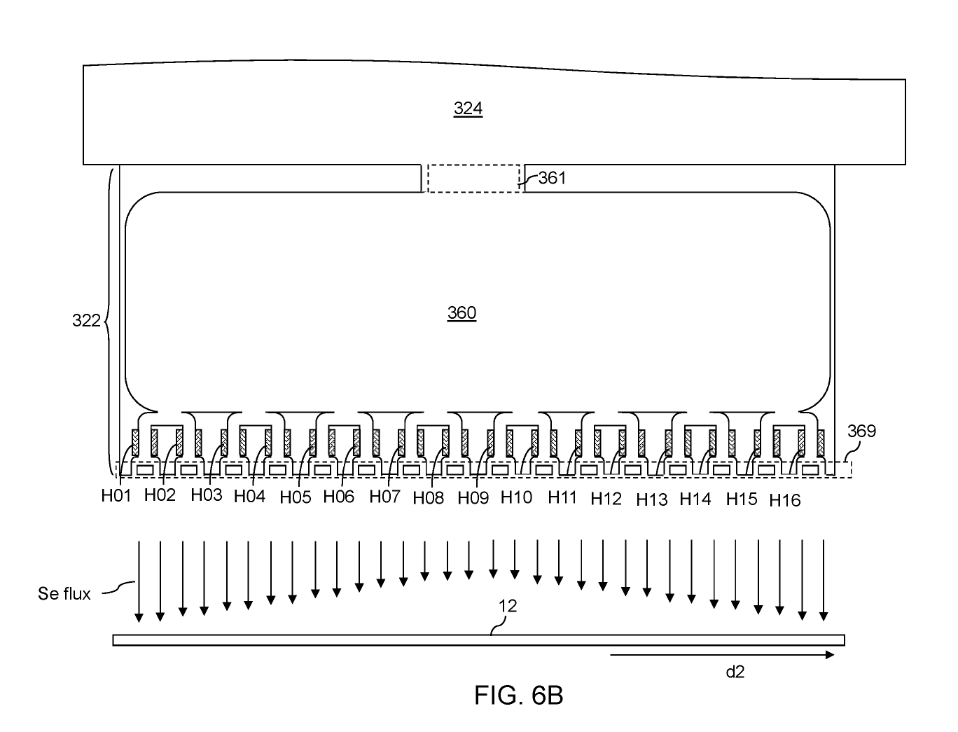

FIGS. 6A and 6B are cross-sectional views of a portion of the second process module 300 that illustrates a configuration of an exemplary gas distribution manifold 322. The exemplary gas distribution manifold 322 may be employed for any, or each, of the gas distribution manifolds 322 illustrated in FIGS. 2, 3, and 5. The cross-sectional view of FIG. 6A is along a plane that is perpendicular to the direction of movement of the substrate 12 within the second process module (i.e., the substrate moves in or out of the page in FIG. 6A).

The second process module 300 includes a deposition system for deposition of a chalcogen-containing compound semiconductor material for forming the p-doped semiconductor layer 30. As discussed above, the deposition system includes a vacuum enclosure attached to a vacuum pump (such as at least one second vacuum pump 380), and a sputtering system comprising at least one sputtering target (such as the at least one metallic component target 310, for example a CIG target) located in the vacuum enclosure and at least one respective magnetron. The sputtering system is configured to deposit a material including at least one component of a chalcogen-containing compound semiconductor material (i.e., the non-chalcogen metallic component(s) of the chalcogen-containing compound semiconductor material) over the substrate 12 in the vacuum enclosure. In other words, the module 300 is a reactive sputtering module in which the chalcogen gas (e.g., selenium vapor) from gas distribution manifolds 322 reacts with the metal (e.g., Cu—In—Ga) sputtered from the targets 310 to form the chalcogen-containing compound semiconductor material (e.g., CIGS) layer 30 over the substrate 12.

The gas distribution manifold 322 has a supply side that is connected to a chalcogen-containing gas source 320 directly or indirectly. The supply side may face the chalcogen-containing gas supply 320 and/or an optional connection manifold 324 that connects the chalcogen-containing gas supply 320 to the gas distribution manifold 322. At least one supply side opening 361 is provided in the gas distribution manifold 322 (e.g., between manifolds 322 and 324). Each supply side opening 361 is a path through which the chalcogen-containing gas is provided into the gas distribution manifold 322.

The gas distribution manifold 322 has a distribution side, which is a different side than the supply side. In one embodiment, the distribution side can be the opposite side of the supply side. The distribution side has at least one set of opening regions 369 facing the substrate 12 and having independent temperature control. The gas distribution manifold 322 includes a manifold enclosure 360 that extends from the at least one supply side opening 361 to the opening regions 369.

In one embodiment, the gas distribution manifold 322 may optionally include at least one branching connections, which may include, for example, bifurcating connections, trifurcating connection, quadrifurcating connections, etc. In case multiple branching connections are employed, the multiple branching connections may be connected in a cascading configuration. In an illustrative example, N stages of bifurcating connections can provide a set of 2^{N} distinct opening regions 369 that are connected to the internal volume of the vacuum enclosure adjacent to the front surface of the substrate 12. In this embodiment, the manifold enclosure 360 may contain a plurality of branching conduits 362 which connect the at least one supply side opening 361 to the opening regions 369, as shown in FIG. 6A. In another embodiment, the manifold enclosure 360 may contain an open space which connects the at least one supply side opening 361 to the opening regions 369, as shown in FIG. 6B.

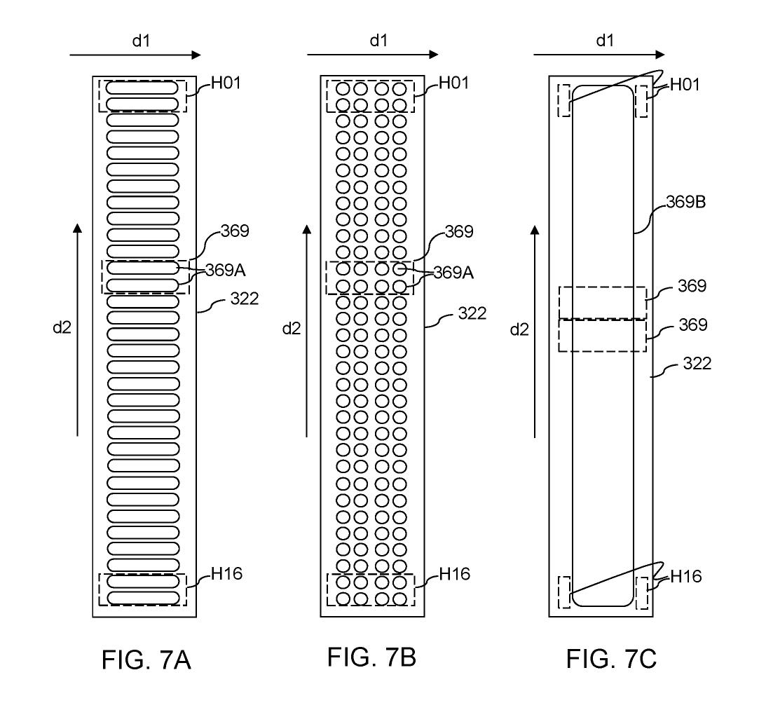

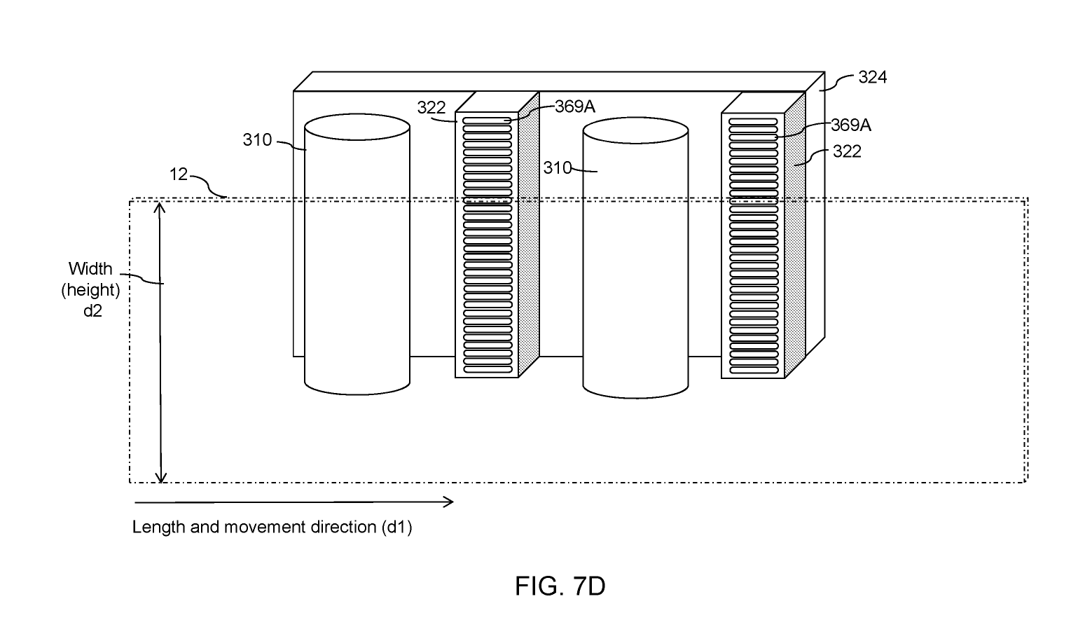

In one embodiment, the deposition system can be configured to continuously move the substrate 12 along a first direction (such a the horizontal direction in and out of the page in FIG. 6A) from an input port (which faces the first processing module 200) of the vacuum enclosure to an output port (which faces the third processing module 400) of the vacuum enclosure of the second processing module 300. In one embodiment, the deposition system can be configured to maintain the front surface of the substrate 12 within a plane that extends along the first direction and a second direction d2 that is perpendicular to the first direction and is along the widthwise (i.e., height) direction of the substrate 12, as shown in FIG. 7D. In one embodiment, each set of opening regions 369 can be configured to be at a substantially same distance from the front surface of the substrate 12. In other words, for any given set of opening regions 369 on the same gas distribution manifold 322, the distance between each opening region 369 and the substrate 12 can be substantially the same. As used herein, distances are substantially the same if the differences in the distances do not exceed 20% of the average of the distances. In one embodiment, the differences in the distances can be less than 1% of the average of the distances. In an alternative embodiment, different sets of opening regions 369 can have different distances between the respective set of opening regions 369 and the front surface of the substrate 12 on which the chalcogen-containing compound semiconductor material is deposited.

Each individual opening region 369 corresponds to an independently temperature-controlled region provided with a respective temperature-controlled heating element H#, in which # represents the numeral assigned to each temperature-controlled heating element. For example, FIG. 6A illustrates hollow (e.g., quasi-cylindrical or cylindrical) temperature-controlled heating elements H01-H16 corresponding to sixteen discrete opening regions 369 located within a single gas distribution manifold 322. While sixteen temperature-controlled heating elements H01-H16 (and correspondingly sixteen opening regions 369) are illustrated in FIGS. 6A, 6B and 7A-7D, it is understood that the number of temperature-controlled heating elements may be selected as needed to provide optimal film uniformity of the deposited chalcogen-containing compound semiconductor material. In general, the number of temperature-controlled heating elements may be in a range from 2 to 100. In one embodiment, the number of temperature-controlled heating elements may be in a range from 5 to 20.

Each set of opening regions 369 includes one or more opening regions 369 arranged along the second direction d2 as illustrated in FIGS. 7A, 7B, 7C and 7D. In one embodiment, each set of opening regions 369 can include a respective set of one or more discrete openings 369A that are spaced from one another at least along the second direction d2 as illustrated in FIGS. 7A, 7B and 7D. In one embodiment illustrated in FIGS. 7A and 7D each set of opening regions 369 may include a one-dimensional array of discrete openings 369A that extend along the second direction d2. In another embodiment illustrated in FIG. 7B, each set of opening regions 369 may include a two-dimensional array of discrete openings 369A that extend along the first direction d1 and along the second direction d2. In this e embodiment, each set of opening regions 369 can include a respective set of discrete openings 369A that are spaced from one another at least along the first direction d1 and along the second direction d2 as illustrated in FIG. 7B. In one embodiment, the two-dimensional array of discrete opening can extend farther along the second direction d2 than along the first direction d1 as illustrated in FIG. 7B.

In another embodiment, the opening regions 369 can include a single continuous opening 369B as illustrated in FIG. 7C. In this case, each opening region 369 is defined by an associated heating region that is independently temperature-controlled. In other words, each region of independent temperature control within the single continuous opening constitutes an opening region 369.

Referring collectively to FIGS. 6A, 6B and 7A-7D, each of the opening regions 369 can comprise a subset of a volume of the gas distribution manifold 322 bounded, at least in part, by a respective subset of surfaces of the gas distribution manifold 322. For example, each of the opening regions 369 can comprise a subset of a volume of the gas distribution manifold 322 bounded by a respective subset of surfaces of the distribution manifold 360 that are laterally surrounded by a respective heating element illustrated in FIGS. 6A and 6B. Locations of a first temperature-controlled heating element H01 and a last temperature-controlled heating element H16 are illustrated in FIGS. 7A-7C.

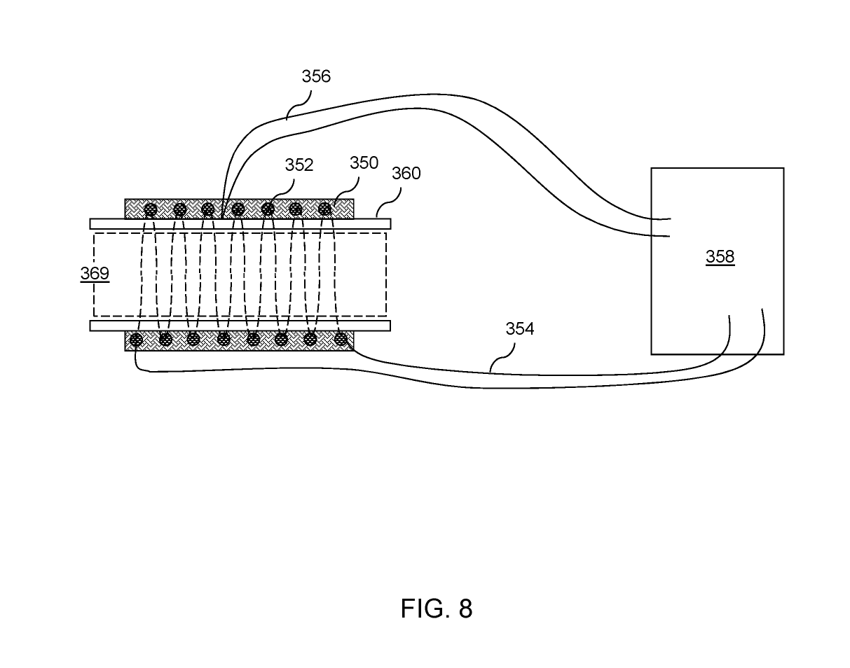

In one embodiment, each heating element can be independently controlled to heat the respective subset of the surfaces of the gas distribution manifold 322 to the same or different temperature from other surfaces of the manifold 322. Referring to FIG. 8, each of the opening regions 369 can be configured to be independently temperature-controlled by a respective combination of a temperature measurement device 356 and a temperature controller 358 providing a controlled power output to a respective heating element 350 (which may comprise any one of heating elements H01 to H016 of FIG. 6A or 6B). For example, the heating element 350 may be a resistive or inductive heating element. The resistive heating element 350 can include a resistive heating wire 352, while the inductive heating element can include an inductor, such as a inductor coil (not shown). An electrical cable 354 can be employed to transmit a controlled voltage output from the temperature controller 358 to the heating element 350.

In one embodiment, the temperature measurement device 356 can be a thermocouple configured to measure temperature of the respective subset of the surfaces of the gas distribution manifold 322, which can be a subset of the surfaces of the manifold enclosure 360. In one embodiment, each subset of the volume of the gas distribution manifold 322 corresponding to an opening region 369 can be bounded by a respective surface of the gas distribution manifold 322, which may be a hollow (e.g., quasi-tubular or tubular) surface of the conduit 362 in the manifold enclosure 360 which terminates in the opening(s) 369A or 369B, as illustrated in FIGS. 6A, 6B, 7A and 7B. In another embodiment, multiple opening regions 369 may be adjoined among one another to form a single continuous opening 369B having multiple temperature-controlled regions as illustrated in FIG. 7C. In this case, different opening regions 369 of the continuous opening 369B may be heated to different temperatures by the independently controlled heating elements 350.

In an illustrative example, the chalcogen-containing compound semiconductor material can comprise a copper indium gallium selenide, and the at least one sputtering target (i.e., the metallic component targets 310) can comprise materials selected from copper, indium, gallium, and alloys thereof (e.g., Cu—In—Ga alloy, CIG). In one embodiment, the chalcogen-containing gas source 320 can be configured to supply a chalcogen-containing gas selected from gas phase selenium and hydrogen selenide (H₂Se). In one embodiment, the chalcogen-containing gas can be gas phase selenium, i.e., vapor phase selenium, which is evaporated from a solid source in an effusion cell.

While the present disclosure is described employing an embodiment in which metallic component targets 310 are employed in the second process module 300, embodiments are expressly contemplated herein in which each, or a subset, of the metallic component targets 310 is replaced with a pair of two sputtering targets (such as a copper target and an indium-gallium alloy target), or with a set of three supper targets (such as a copper target, an indium target, and a gallium target).

Generally speaking, the chalcogen-containing compound semiconductor material can be deposited by providing a substrate 12 in a vacuum enclosure attached to a vacuum pump 380, providing a sputtering system comprising at least one sputtering target 310 located in the vacuum enclosure and at least one respective magnetron located inside a cylindrical target 310 or behind a planar target (not explicitly shown), and providing a gas distribution manifold 322 having a supply side and a distribution side. The distribution side has at least one set of opening regions 369 facing the substrate 12 and having independent temperature control, and the supply side is connected to a chalcogen-containing gas source 320. The chalcogen-containing compound semiconductor can be deposited by sputtering a material including at least one component (i.e., the non-chalcogen component) of a chalcogen-containing compound semiconductor material onto the substrate 12 while flowing a chalcogen-containing gas (e.g., Se vapor) into the vacuum chamber through the gas distribution manifold 322 and while providing a non-uniform temperature profile within a set of opening regions 369 that is selected from the at least one set of opening regions 369.

Each set of opening regions 369 may have an independent temperature profile (i.e., independently controlled temperature), such that a temperature of a given opening region 369 is either the same and/or different from the temperature of one or more other opening regions 369 in the same manifold 322 at a given time.

In one embodiment, without wishing to be bound by a particular theory, the present inventors determined that a higher chalcogen (e.g., selenium) flux is desirable at the ends (i.e., top and bottom portions of a vertically positioned web substrate in direction d2 in FIG. 7D) than in the middle of the vertically positioned substrate to obtain a metal chalcogen containing compound semiconductor material (e.g., CIGS) with a more uniform thickness and/or composition as a function of substrate width (i.e., height) in direction d2. In one embodiment, the manifold 322 contains independently controllable heating elements 350 (e.g., H01 to H16) which can be independently controlled to provide a lower temperature at the end opening regions 369 than the middle opening regions 369 of the same manifold. In other words, the end heating elements (e.g., H01, H02, H15 and H16) are maintained at a lower temperature than the middle heating elements (e.g., H07, H08, H09 and H10) at a given time. It is believed that the lower heating element temperature results in a higher selenium vapor flux from the respective opening region. Thus, a higher selenium flux is provided from the end opening regions 369 than the middle opening regions 369 of the same manifold 322 at the same time, as shown in by the length of the arrows in FIGS. 6A and 6B. The higher chalcogen (e.g., selenium vapor) flux to the ends than the middle of the web substrate 12 can enhance the uniformity of the composition and thickness of the deposited chalcogen-containing compound semiconductor material (e.g., the p-CIGS absorber layer 30). Thus, the non-uniform temperature profile of the opening regions 369 (e.g., lower temperature of the end regions than middle regions) can compensate for the non-uniformity of the substrate temperature and the non-uniformity of the local reactant composition to provide a CIGS absorber layer 30 by reactive sputtering with improved compositional uniformity and thickness uniformity without using moving parts, such as valves, to control relative selenium flux.

Thus, in one embodiment, first respective heating elements 350 located adjacent to opening regions 369 at the ends of the gas distribution manifold 322 are configured to be at a lower temperature than second respective heating elements 350 located adjacent to opening regions 369 at a middle of the gas distribution manifold 322 to provide a higher selenium flux from the opening regions at the ends of the gas distribution manifold than from the opening regions at the middle of the gas distribution manifold.

In one embodiment, the substrate 12 can be provided as a vertically oriented moving web having the middle located below the first end and above the second end. The substrate 12 can be continuously moved along a first direction d1 from an input port on the vacuum enclosure to an output port on the vacuum enclosure. In one embodiment, the front surface of the substrate 12 can be maintained within a plane that extends along the first direction d1 and a second direction d2 that is perpendicular to the first direction d1 and is along a widthwise direction of the substrate 12. In one embodiment, each set of opening regions 369 can be configured to be at a substantially same distance from the front surface of the substrate 12. In other words, the plane of the front surface of the substrate 12 can be maintained at a uniform distance from all opening regions 369 for each set of opening regions 369.

The selenium vapor flows to the substrate 12 through the gas distribution manifold 322 having a plurality of opening regions 369 facing the substrate 12. First opening regions 369 located at ends of the gas distribution manifold 322 and facing the ends of the substrate 12 are maintained at a lower temperature than second opening regions 369 located at a middle of the gas distribution manifold 322 and facing the middle of the substrate 12 to provide a higher selenium flux to the ends of the substrate 12 than to the middle of the substrate 12.

Referring back to FIGS. 2 and 3, the portion of the substrate 12 on which the first electrode 20 and the p-doped semiconductor layer 30 are deposited is subsequently passed into the third process module 400. An n-doped semiconductor material is deposited in the third process module 400 to form the n-doped semiconductor layer 40 illustrated in the photovoltaic cell 10 of FIG. 1. The third process module 400 can include, for example, a third sputtering target 410 (e.g., a CdS target) and a magnetron (not expressly shown). The third sputtering target 410 can include, for example, a rotating AC magnetron, an RF magnetron, or a planar magnetron.

The portion of the substrate 12 on which the first electrode 20, the p-doped semiconductor layer 30, and the n-doped semiconductor layer 40 are deposited is subsequently passed into the fourth process module 500. A transparent conductive oxide material is deposited in the fourth process module 500 to form the second electrode comprising a transparent conductive layer 50 illustrated in the photovoltaic cell 10 of FIG. 1. The fourth process module 500 can include, for example, a fourth sputtering target 510 and a magnetron (not expressly shown). The fourth sputtering target 510 can include, for example, a ZnO, AZO or ITO target and a rotating AC magnetron, an RF magnetron, or a planar magnetron. A transparent conductive oxide layer 50 is deposited over the material stack (30, 40) including the p-n junction. In one embodiment, the transparent conductive oxide layer 50 can comprise a material selected from tin-doped indium oxide, aluminum-doped zinc oxide, and zinc oxide. In one embodiment, the transparent conductive oxide layer 50 can have a thickness in a range from 60 nm to 1,800 nm.

Subsequently, the web substrate 12 passes into the output module 800. The substrate 12 can be wound onto the output spool 810 (which may be a take up spool) as illustrated in FIG. 2, or can be sliced into photovoltaic cells using a cutting apparatus 840 as illustrated in FIG. 3.

While sputtering was described as the preferred method for depositing all layers onto the substrate, some layers may be deposited by MBE, CVD, evaporation, plating, etc. It is to be understood that the present invention is not limited to the embodiment(s) and the example(s) described above and illustrated herein, but encompasses any and all variations falling within the scope of the appended claims. For example, as is apparent from the claims and specification, not all method steps need be performed in the exact order illustrated or claimed, but rather in any order that allows the proper formation of the photovoltaic cells of the present invention.

1. A deposition system for deposition of a chalcogen-containing compound semiconductor material, comprising:
a vacuum enclosure connected to a vacuum pump;
a sputtering system comprising at least one sputtering target located in the vacuum enclosure, wherein the sputtering system is configured to deposit a material including at least one component of a chalcogen-containing compound semiconductor material over a substrate in the vacuum enclosure;
a chalcogen-containing gas source; and
a gas distribution manifold having a supply side and a distribution side,
wherein:
the distribution side has a plurality of opening regions having independent temperature control;
the supply side is connected to the chalcogen-containing gas source;
the gas distribution manifold comprises a volume of a manifold enclosure that extends from at least one supply side opening located at the supply side to the plurality of opening regions;
each of the plurality of opening regions comprises a subset of a volume of the gas distribution manifold bounded, at least in part, by a respective subset of surfaces of the gas distribution manifold; and
a plurality of heating elements are located outside the manifold enclosure and adjacent to the respective subset of the surfaces of the gas distribution manifold and are configured to provide the independent temperature control for the plurality of opening regions.

2. The deposition system of claim 1, wherein the deposition system further comprises at least one spool or roller configured to continuously move the substrate in a vertical orientation along a first direction from an input port on the vacuum enclosure to an output port on the vacuum enclosure.

3. The deposition system of claim 2, wherein the deposition system is configured to maintain a front surface of the substrate within a plane that extends along the first direction and a second direction that is perpendicular to the first direction and is along a widthwise direction of the substrate.

4. The deposition system of claim 3, wherein the plurality of opening regions comprises a plurality of openings arranged along the second direction.

5. The deposition system of claim 3, wherein the plurality of opening regions comprises a two-dimensional array of discrete openings that extend along the first and the second directions.

6. The deposition system of claim 3, wherein the plurality of opening regions includes a single continuous opening having independent temperature control at different regions of the single continuous opening.

7. (canceled)

8. The deposition system of claim 1, wherein each respective heating element comprises a resistive or inductive heating element.

9. (canceled)

10. The deposition system of claim 1, wherein:
the respective subset of surfaces of the gas distribution manifold comprises a respective conduit in the gas distribution manifold leading to a respective one of the plurality of opening regions; and
the respective heating element is located adjacent to the respective conduit.

11. The deposition system of claim 10, wherein each of the opening regions is configured to be temperature controlled by a respective combination of a temperature measurement device and a temperature controller providing a controlled power output to the respective heating element.

12. The deposition system of claim 11, wherein the temperature measurement device is a thermocouple configured to measure temperature of the respective subset of the surfaces of the gas distribution manifold.

13. The deposition system of claim 1, wherein:
the chalcogen-containing compound semiconductor material comprises copper indium gallium selenide;
the at least one sputtering target comprises materials selected from copper, indium, gallium, and alloys thereof; and
the chalcogen-containing gas source comprises a selenium evaporator.

14. The deposition system of claim 13, wherein first respective heating elements located adjacent to opening regions at the ends of the gas distribution manifold are configured to be at a lower temperature than second respective heating elements located adjacent to opening regions at a middle of the gas distribution manifold to provide a higher selenium flux from opening regions at the ends of the gas distribution manifold than from opening regions at the middle of the gas distribution manifold.

15. A deposition system for deposition of a copper indium gallium selenide compound semiconductor material, comprising:
a vacuum enclosure connected to a vacuum pump;
a sputtering system comprising at least one sputtering target located in the vacuum enclosure, wherein the at least one sputtering target comprises at least one of copper, gallium and indium;
a selenium evaporator;
a gas distribution manifold having a supply side and a distribution side, wherein the distribution side has a plurality of opening regions and the supply side is connected to the selenium evaporator; and
a plurality of heating elements configured to independently heat at least a first opening region of the plurality of opening regions to a different temperature than at least a second opening region of the plurality of opening regions,
wherein:
the gas distribution manifold comprises a volume of a manifold enclosure that extends from at least one supply side opening located at the supply side to the plurality of opening regions;
each of the plurality of opening regions comprises a subset of a volume of the gas distribution manifold bounded, at least in part, by a respective subset of surfaces of the gas distribution manifold; and
the plurality of heating elements are located outside the manifold enclosure and adjacent to the respective subset of the surfaces of the gas distribution manifold and are configured to provide independent temperature control for the plurality of opening regions.

16. The deposition system of claim 15, wherein the plurality of heating elements comprises:
first heating elements for heating the opening regions located at ends of the gas distribution manifold to a first temperature; and
second heating elements for heating the opening regions located at a middle of the gas distribution manifold to a second temperature higher than the first temperature, such that a higher selenium flux is provided from the opening regions at the ends of the gas distribution manifold than from opening regions at the middle of the gas distribution manifold.

17.-20. (canceled)

21. The deposition system of claim 1, wherein the gas distribution manifold includes at least one branching connection between the source side and the distribution side.

22. The deposition system of claim 1, wherein the gas distribution manifold includes a plurality of branching connections that are connected in a cascading configuration.

23. The deposition system of claim 1, wherein the plurality of heating elements are located around tubular surfaces of conduits of the manifold enclosure that are located at the distribution side.

24. The deposition system of claim 15, wherein the gas distribution manifold includes at least one branching connection between the source side and the distribution side.

25. The deposition system of claim 15, wherein the gas distribution manifold includes a plurality of branching connections that are connected in a cascading configuration.

26. The deposition system of claim 15, wherein the plurality of heating elements are located around tubular surfaces in conduits in the manifold enclosure that are located at the distribution side.
